(19) United States
(12) Patent Application Publication
(10) Pub. No.: US 2001/0052324 A1
(43) Pub. Date: Dec. 20, 2001

(54) Device for producing and processing semiconductor substrates

(76) Inventors: Roland Rupp, Lauf (DE); Arno Wiedenhofer, Regensburg (DE)

Correspondence Address: LERNER AND GREENBERG, P.A., Post Office Box 2480, Hollywood, FL, 33022-2480, US

(21) Appl. No.: 09/799,668

(22) Filed: Mar. 5, 2001

Related U.S. Application Data
(63) Continuation of application No. PCT/DE99/02645, filed on Aug. 24, 1999.

(30) Foreign Application Priority Data
Sep. 3, 1998 (DE) 198 40 227.9

(51) Int. Cl. C23C 16/00

(52) U.S. Cl. 118/728; 118/715

(57) ABSTRACT

The device for producing and processing silicon carbide semiconductor substrates at a high temperature has a susceptor, on which the semiconductor substrates rest, so that there is good thermal contact between the semiconductor substrates and the susceptor. To ensure that there is no contamination of the component during the production process, the surface of the susceptor is covered with cover plates each formed with a cutout for a semiconductor substrate. The surface of the susceptor is substantially completely covered by the cover plates and the semiconductor substrates.

### CROSS-REFERENCE TO RELATED APPLICATION

This application is a continuation of copending International Application No. PCT/DE99/02645, filed Aug. 24, 1999, which designated the United States.

### BACKGROUND OF THE INVENTION

### FIELD OF THE INVENTION

The invention lies in the field of semiconductor manufacture and relates, more specifically, to a device for producing and processing at least one semiconductor substrate at a high temperature using a susceptor, on which the at least one semiconductor substrate rests, so that there is good thermal contact between the semiconductor substrate and the susceptor. In this context, the processing involves in particular the coating of substrates. The invention also relates to the use of the device.

Silicon carbide (SiC) epitaxy is usually carried out at a high temperature, that is, at temperatures of over 1300° C. To achieve high growth rates of more than 4 μm/h, the epitaxy is also carried out at temperatures of more than 1450° C. The process atmosphere consists predominantly of hydrogen with additions of silicon-containing and carbon-containing gases, such as silane and propane. Under these process conditions, the selection of the materials situated in the hot area of the reactor is key to the production of SiC layers of sufficient purity, i.e. with a level of impurities which lies below 10¹⁵ cm⁻³.

With all materials which are used at high temperatures in the prior art (e.g. graphite, Mo, W, Ta, Nb), impurities such as aluminum, boron and titanium are released as gases (diffused out) at these temperatures. In the case of graphite, which is used as the classic high-temperature material, in addition to the gaseous evolution of aluminum, boron and titanium, reactions with the hydrogen atmosphere also take place, leading to the formation of hydrocarbon compounds. As a result, the carbon concentration in the process atmosphere and therefore also the growth conditions for the epitaxial layer are altered in a scarcely controllable manner. The impurities which are released from the graphite or the metals employed are incorporated in the epitaxial layer and likewise change the electrical properties thereof in an uncontrollable manner. Consequently, these layers often become unusable for the production of components or lead to a very low yield.

During the production and processing of SiC epitaxial layers, SiC substrates are positioned on a susceptor and are then coated, etched and, if appropriate, annealed etc. after implantation at elevated temperatures in a reactor. A device of this type for producing high-purity or specifically doped epitaxial SiC layers is described in U.S. Pat. No. 5,119,540 to Kong et al. The high purity of the epitaxial layers is achieved by the fact that the concentration of residual nitrogen in the environment of the substrate during the chemical vapor deposition (CVD) process is reduced. For this purpose, in the above-mentioned device, supports made from pure SiC are used for the substrates or wafers, i.e., pure SiC susceptors are used.

However, the drawback of susceptors made from pure SiC is that at low temperatures they are very difficult to connect to a HF heating arrangement. Furthermore, when SiC susceptors are used, there is an undesirable growth of SiC on the back surface of the substrates, i.e. at the point where the substrate rests on the susceptor. Moreover, the SiC susceptors are highly complex and expensive to produce.

International published application WO 96/23913 describes a process for protecting a susceptor, by means of which the service life of the susceptor is prolonged under the conditions of an epitaxial growth process for SiC or III-V nitrates. For this purpose, a plate is arranged on the susceptor, which plate comprises SiC or an alloy of SiC and the material which is grown and on which plate the substrate is positioned. However, since the plate at least partially comprises SiC, in this case too undesirable growth of SiC takes place on the back surface of the substrate.

Moreover, the prior art uses supports formed of graphite and coated with SiC for the substrates, susceptors and further parts. To prevent the formation of cracks and to prevent the SiC layer from flaking off the graphite, however, the thickness of the layer may be at most approximately 100 μm. As a result, the service life of the supports and parts is limited, since the SiC layer in the process, on account of thermally driven transfer processes, generally becomes increasingly thin at some points and ultimately disappears altogether. Also, cracks often develop in the coating. A further drawback of the SiC-coated graphite parts is the undesirable growth on the bearing surface of the substrate.

Furthermore, Japanese published patent application JP 02-212394 discloses a susceptor which comprises a susceptor core and a wafer insert attached thereto. The core is produced by forming a coating on a graphite substrate by means of CVD and polishing the surface of the core. The wafer insert is made from silicon carbide, silicon nitride, silicon, or quartz.

### SUMMARY OF THE INVENTION

The object of the present invention is to provide a device for producing semiconductor substrates which overcomes the above-noted deficiencies and disadvantages of the prior art devices and methods of this general kind, and which, during the production process, does not have an adverse effect on a preset composition of a process atmosphere, does not contribute to contamination of the epitaxial layer which is to be grown, does not alter the back surface of the substrate, and can be produced cost-effectively.

With the above and other objects in view there is provided, in accordance with the invention, a device for producing and processing SiC semiconductor substrates at elevated temperatures, comprising:

a susceptor having a support surface configured to support semiconductor substrates during processing, and ensuring good thermal contact between the support surface and the semiconductor substrates;

a plurality of cover plates directly covering the support surface of the susceptor and each having a cutout formed therein for receiving a respective semiconductor substrate;

the cover plates and the semiconductor substrates substantially completely covering the support surface of the susceptor and ensuring good conduction of heat between the susceptor and the cover plates.

In accordance with an added feature of the invention, the cover plates are spaced a distance of less than 0.5 mm from one another and from the respective semiconductor substrate.

In accordance with a concomitant feature of the invention, the cover plates consist of polycrystalline SiC or of metal carbide.

The solution to the above object substantially consists in covering the support for the substrate as completely as possible with SiC covers in the areas surrounding the substrates. The SiC covering prevents contaminants which are released from the susceptor from passing into the atmosphere in the process chamber and thus possibly becoming incorporated in, for example, the epitaxial layer on a substrate. To make the covering more effective, the distance between the substrates and the surrounding SiC covers is kept as small as possible. The covering is composed of a plurality of individual SiC cover plates in order, for example, to reduce production costs and to lower the risk of fracture caused by thermal stresses. In this case, the distance both between the individual cover plates and the substrate and between the various cover plates is kept as small as possible.

In the device according to the invention for producing and processing semiconductor substrates at a high temperature using a susceptor, on which the semiconductor substrates rest, so that there is good thermal contact between the semiconductor substrates and the susceptor, a covering which has a cutout for the semiconductor substrate is provided on the surface of the susceptor. The surface of the susceptor—especially in the process-gas stream upstream of the substrate—is substantially completely covered by the covering and the semiconductor substrate.

The covering comprises a plurality of cover plates which are at a distance of less than 0.5 mm from one another and from the semiconductor substrate. This ensures that the minimum possible amount of contaminating substances can be released as gases through the spaces between the cover plates and thus impair the purity of the semiconductor layer which is growing. In particular, the covering consists of polycrystalline SiC. The result is a substantially uniform surface in the reactor which has identical optical properties everywhere, which is advantageous for example for pyrometric inspection measurements. However, the covering may equally well consist of the metal carbides molybdenum carbide MoC, tantalum carbide TaC, tungsten carbide WC or niobium carbide NbC.

To achieve good conduction of heat between the covering and the susceptor and to make a reaction with the hydrogen atmosphere more difficult, the covering preferably rests directly on the susceptor.

The device is used in particular for producing and processing a semiconductor layer or a semiconductor substrate made from SiC.

One advantage consists in the fact that the substrate rests directly on the susceptor and is not simply heated indirectly via an SiC covering or an intermediate layer. Therefore, there are no undesirable growths on the back surface of the substrate. Moreover, as a result the thermal boundary conditions for the environment surrounding the substrate are the same as those for the substrate itself, in particular with a substrate made from SiC: in both cases, the heat is transferred from the support, i.e. from the susceptor, to the SiC covering and the SiC substrate by radiation with substantially the same thermal coupling. This makes the temperature distribution on the substrate and in its immediate vicinity more homogeneous.

Other features which are considered as characteristic for the invention are set forth in the appended claims.

Although the invention is illustrated and described herein as embodied in a device for producing and processing semiconductor substrates, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a cross section taken through a first exemplary embodiment of the device;

FIG. 2 is a section taken through a second exemplary embodiment of the device;

FIG. 3A is a plan view onto an exemplary embodiment of the device for a plurality of semiconductor substrates; and

FIG. 3B is a cross section through the exemplary embodiment of the device which illustrated in FIG. 3A.

### DESCRIPTION OF THE PREFERRED EMBODIMENTS

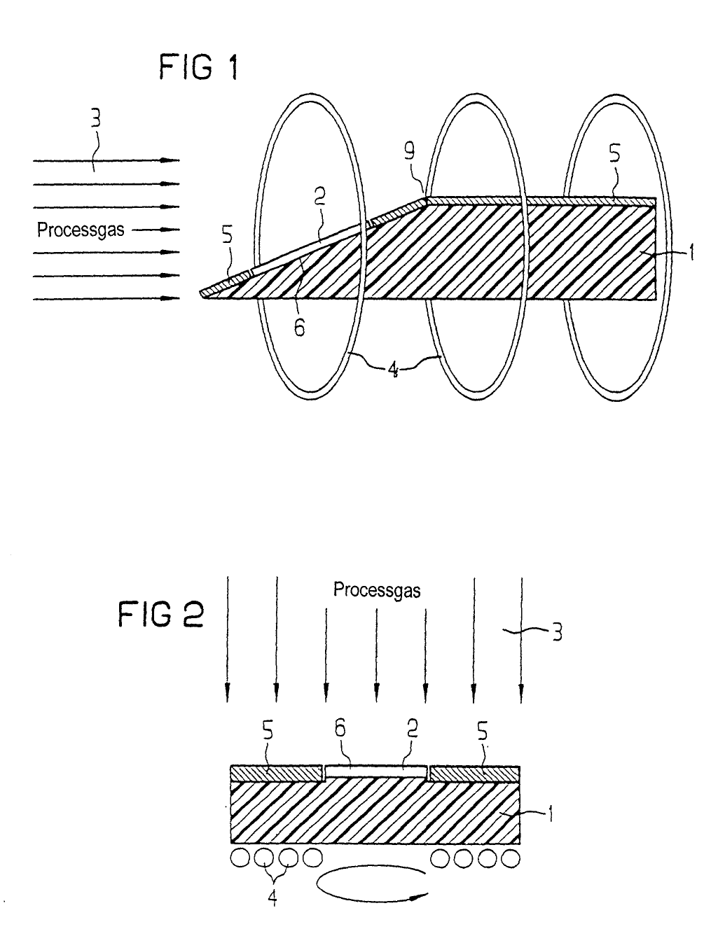

Referring now to the figures of the drawing in detail and first, particularly, to FIG. 1 thereof, there is seen, as an exemplary embodiment of the invention, a horizontal reactor, in which a susceptor 1, which consists in particular of metal or graphite, is arranged in a non-illustrated horizontal quartz tube. A semiconductor substrate 2 which is to be processed is arranged on the susceptor 1. One surface of the semiconductor substrate 2 lies fully on the susceptor 1, so that there is good thermal contact between susceptor 1 and the substrate 2. This ensures that heat is supplied to the semiconductor substrate 2 via the susceptor 1, so that the desired reactions can take place on the exposed surface of the substrate 2.

The desired reactions are initiated in particular by vapor deposition processes, such as CVD. In this case, selected process gases are passed over the heated substrate(s) 2 on which a desired layer is to be deposited. The process gas flowing onto the susceptor 1 is denoted by 3 in FIG. 1, and its direction of flow is indicated by a plurality of parallel arrows. The composition of the process gas 3 depends on the intended processing of the semiconductor substrate 2. The process gases react on the hot substrate surface, during which period the temperature, depending on the process gas, lies in a range between a few hundred and up to 1600° C. The reaction products result in the desired layer being formed on the surface of the substrate 2, and residual gases are extracted from the reactor by suction.

In the embodiment illustrated, the susceptor 1 is beveled on the side on which the substrate 2 is supported. The inclination of the substrate results in a specifically set flow of the process gases 3 over the surface of the respective substrate 2, so that the deposition processes on the substrate surface take place uniformly.

To shield the chamber atmosphere from the process gases 3, the susceptor 1 is preferably arranged in a non-illustrated tube. In the embodiment of the reactor which is illustrated in FIG. 1, the susceptor 1 is inductively heated. For this purpose, a coil 4 is provided which surrounds the tube and is supplied with a HF voltage.

The susceptor 1 consists of a metal, such as molybdenum or tungsten, or of graphite. Further materials from which the susceptor may be produced are materials which scarcely react chemically with the substrate, such as, in addition to molybdenum and tungsten, also tantalum or niobium. In other words, with these materials there is only a very reduced level of material removed on the back surface of the substrate 2 made from SiC as a result of the formation of metal carbides and metal suicides with the susceptor 1. In particular, the susceptor 1 may also consist of an alloy of the above-mentioned metals. Furthermore, the susceptor 1 may also be made from graphite.

As explained above, the thermal contact between the susceptor 1 and the substrate 2 must be good, so that the temperatures which are required for the desired reactions on the surface of the substrate 2 are reached.

Heating the susceptor 1 to high temperatures in the range of up to 1600° C. causes gaseous evolution of the material of the susceptor 1. The gases released may lead to considerable undesirable contamination of the semiconductor substrates 2. To prevent this contamination, a covering 5 is arranged on the hot surfaces of the susceptor 1. The covering 5 preferably consists of SiC or metal carbides which are able to withstand high temperatures. The covering 5 is formed with a cutout 6 which is sufficiently large for it to be able to accommodate the substrate 2 on which epitaxial growth is to take place.

The distance between the covering 5 and the substrate 2 to be processed is kept as small as possible, so that little gas originating from the susceptor 1 can emerge from the gaps between the covering 5 and the substrate 2. In practice, a distance of at most 0.5 mm between the covering 5 and the substrate 2 has proven advantageous.

In particular, the covering 5 comprises a plurality of plates 7, which preferably consist of SiC. The division of the covering 5 into individual plates 7 allows the covering 5 to be flexibly adapted to the geometry of the susceptor 1, without a dedicated covering 5 having to be produced for each form of susceptor 1. In this way, it is possible, inter alia, to reduce the production costs and to lower the risk of fracture caused by thermal stresses. For example, it is possible for the area surrounding the substrate 2 to be almost completely covered despite the susceptor 1 having steps and edges 9, as shown in FIG. 1.

A second exemplary embodiment of the device is illustrated in FIG. 2. Here, the susceptor 1 is configured as a plate and is mounted on a spindle so that it can rotate about its center. The rotation is schematically indicated by the arrow below the assembly. As a result, the susceptor 1 can be rotated during the processing of the substrate 2, so that non-uniform supply of process gases 3 or uneven heating over a prolonged period are avoided by this averaging effect. That side of the susceptor 1 onto which the process gases 3 flow is covered by an SiC covering 5 with a cutout 6 for a substrate 2. The cutout 6 and the substrate 2 in it are preferably arranged on the susceptor 1 in such a way that the center of the cutout 6 coincides with the axis of rotation of the susceptor 1. The susceptor 1 is inductively heated by a flat coil 4. The susceptor 1 may also be configured as a rotary crucible with an internal HF coil 4.

The vertical reactor shown in FIG. 2 is particularly suitable for a single substrate 2 or a single wafer (single-wafer reactor).

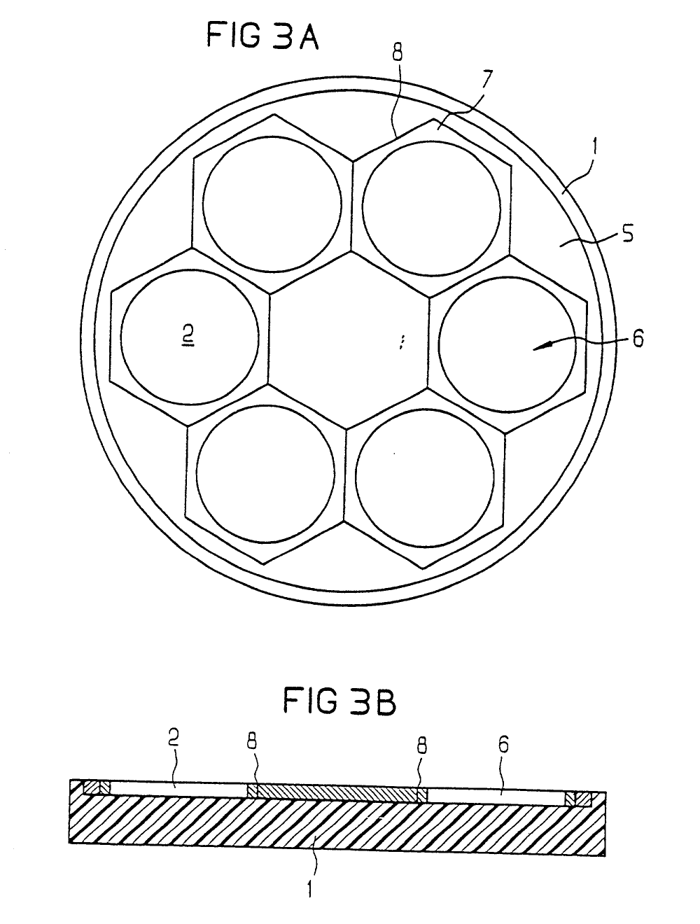

A device for a vertical reactor which is suitable for processing a plurality of substrates (multi-wafer reactor) is illustrated in plan view in FIG. 3A. This device is also shown in cross section in FIG. 3B. Here, the susceptor 1 is likewise covered with plates and it is mounted on a non-illustrated spindle so that it can rotate about its center. However, unlike in the above exemplary embodiment shown in FIG. 2, there are here a plurality of substrates resting on the susceptor 1. The size of the susceptor 1 is selected in such a way that the desired number of substrates 2 can be accommodated thereon. This means that it is possible for a plurality of substrates 2 to be arranged in a circle around the spindle of the susceptor 1, but also it is possible for further substrates 2 to be arranged in a non-illustrated additional circle around the spindle of the susceptor 1. In this case too, a flat coil is used for the inductive heating of the susceptor 1 and the semiconductor substrates 2.

As has been explained with reference to FIG. 1, in the embodiment with a plurality of SiC cover plates 7, the substrates 2 are completely surrounded by the SiC cover plates 7, so that gas is substantially no longer able to pass from the susceptor 1 into the process atmosphere and contribute to undesirable contamination of, for example, epitaxial layers on the substrate 2. It is clear from the illustration shown in FIG. 3A that cover plates 7 which are designed as hexagonal tiles are particularly suitable for virtually complete covering of the area surrounding the substrate 2.

The distance between the individual plates 7 and the distance from the individual plates to the substrate 2 to be processed is kept as small as possible, so that little gas originating from the susceptor 1 is able to emerge even from the gaps between the plate 7 and between plates 7 and the substrate 2. In practice, a distance of at most 0.5 mm between an edge 8 of one plate 7 and the edge 8 of an adjacent plate 7 and between the edge 8 of a plate 7 and the substrate 2 has proven advantageous.

To make the distribution of heat on the substrate as homogenous and uniform as possible, it is necessary for the temperature to be as identical as possible throughout, even in the area surrounding the substrate. In other words, the temperature on the freely accessible surface of the substrate must be the same as on the surface of the covering 5. Therefore, the covering 5 is preferably arranged directly on the susceptor 1, so that there is good conduction of heat between susceptor 1 and covering 5. This is the case in particular if both substrate 2 and covering 5 consist of SiC, i.e. the covering 5 consists of polycrystalline high-purity SiC and therefore has very similar thermal properties to those of the substrate. The thermal coupling between the susceptor 1 and the covering 5 means that the covering 5 reaches substantially the same temperature as the substrate 2. Making the covering 5 from polycrystalline high-purity SiC leads to particularly good conduction of heat. Furthermore, a covering of polycrystalline SiC leads to a homogeneous surface of SiC (namely covering 5 and substrate 2) in the reactor, which simplifies pyrometric examinations for determining the surface temperature and the like.

The device described is used in particular for producing and processing SiC substrates, since the covering of SiC can be used even at the high temperatures required for, for example, SiC epitaxy.

The device can be employed in various types of reactors, for example hot-wall or cold-wall reactors, reactors in which the susceptor is heated directly by a heating winding or a heater lamp, or reactors for plasma-enhanced CVD, etc.

We claim:

1. A device for producing and processing SiC semiconductor substrates at elevated temperatures, comprising:
a susceptor having a support surface configured to support semiconductor substrates, and ensuring good thermal contact between said support surface and the semiconductor substrates;
a plurality of cover plates directly covering said support surface of said susceptor and each having a cutout formed therein for receiving a respective semiconductor substrate;
said cover plates and the semiconductor substrates substantially completely covering said support surface of said susceptor and ensuring good conduction of heat between said susceptor and said cover plates.

2. The device according to claim 1, wherein said cover plates are spaced a distance of less than 0.5 mm from one another and from the respective semiconductor substrate.

3. The device according to claim 1, wherein said cover plates consist of polycrystalline SiC.

4. The device according to claim 1, wherein said cover plates consist of metal carbide.
